(19) United States
(12) Patent Application Publication
(10) Pub. No.: US 2023/0245969 A1
(43) Pub. Date: Aug. 3, 2023

(54) SEMICONDUCTOR APPARATUS

(71) Applicant: Mitsubishi Electric Corporation, Tokyo (JP)

(72) Inventors: Masaya IMORI, Tokyo (JP); Daisuke KAWABATA, Tokyo (JP)

(73) Assignee: Mitsubishi Electric Corporation, Tokyo (JP)

(21) Appl. No.: 17/938,296

(22) Filed: Oct. 5, 2022

(30) Foreign Application Priority Data
Jan. 31, 2022 (JP) 2022-012940

(51) Int. Cl. H01L 23/498; H01L 23/00; H01L 25/07

(52) U.S. Cl. CPC H01L 23/49866; H01L 24/48; H01L 24/73; H01L 24/32; H01L 24/29; H01L 24/83; H01L 24/27; H01L 25/072; H01L 2924/35121; H01L 2924/13055; H01L 2924/13091; H01L 2924/12032; H01L 2924/10272; H01L 2924/1033; H01L 2924/10254; H01L 2224/8384; H01L 2224/2732; H01L 2224/83097; H01L 2224/29139; H01L 2224/29147; H01L 2224/83359; H01L 2224/83345; H01L 2224/83385; H01L 2224/3207; H01L 2224/3201; H01L 2224/32245; H01L 2224/48225; H01L 2224/73265; H01L 2224/48137

(57) ABSTRACT

According to the present disclosure, a semiconductor apparatus comprises an insulating substrate. A porous material is directly bonded to the insulating substrate. And a semiconductor device is bonded to the porous material via a bonding material. The bonding material contains metal nanoparticles.

### BACKGROUND OF THE INVENTION

### Field

The present disclosure relates to a semiconductor apparatus using a bonding material containing metal nanoparticles.

### Background

JP 2006-202944 A discloses a bonding method and a bonding structure using a bonding material containing metal nanoparticles. An organic protective film covering the metal nanoparticles and an organic solvent required for pasting have been used for the bonding material. Such organic substances need to be volatilized at the time of bonding. However, there has been a problem that when a bonding surface is large, its central portion is difficult to satisfactorily volatilize.

JP 2006-202944 A discloses that a porous metal layer is installed between two members to be bonded to each other as a method for solving the problem. In this method, the porous metal layer is first bonded to the lower layer member using a bonding material. Then, the upper layer member is bonded to the porous metal layer using a bonding material. This method makes it possible to satisfactorily volatilize the organic substances because holes of the porous metal layer can be utilized as a volatilization path.

However, in the above-described method, bonding using a bonding material needs to be performed at two positions, i.e., the top and bottom of the porous metal layer. When printing and sintering are collectively performed, there occurs a problem that the thickness of the bonding material varies, resulting in a deterioration in product reliability, because the bonding material printed the first time is crushed when printed the second time. When printing and sintering are performed two times at the top and bottom of the porous metal layer, there occurs a problem that a large number of man-hours are required.

### SUMMARY

In view of the above-described problems, an object of the present disclosure is to provide a semiconductor apparatus in which a printing thickness of a bonding layer is uniform, and a required number of man-hours is small.

The features and advantages of the present disclosure may be summarized as follows.

A semiconductor apparatus according to the present disclosure includes: an insulating substrate; a porous material directly bonded to the insulating substrate; and a semiconductor device bonded to the porous material via a bonding material containing metal nanoparticles.

Other and further objects, features and advantages of the disclosure will appear more fully from the following description.

### BRIEF DESCRIPTION OF DRAWINGS

FIG. 1 is a cross-sectional view according to a first embodiment of the present invention.

FIG. 2 is a cross-sectional view of a bonding structure according to a second embodiment of the present disclosure.

FIG. 3 is a plan view of the bonding structure according to the second embodiment of the present disclosure.

FIG. 4 is a cross-sectional view of a bonding structure according to a third embodiment of the present disclosure.

FIG. 5 is a plan view of the bonding structure according to the third embodiment of the present disclosure.

FIG. 6 is a cross-sectional view of a bonding structure according to a fourth embodiment of the present disclosure.

FIG. 7 is a plan view of the bonding structure according to the fourth embodiment of the present disclosure.

### DESCRIPTION OF EMBODIMENTS

### First Embodiment

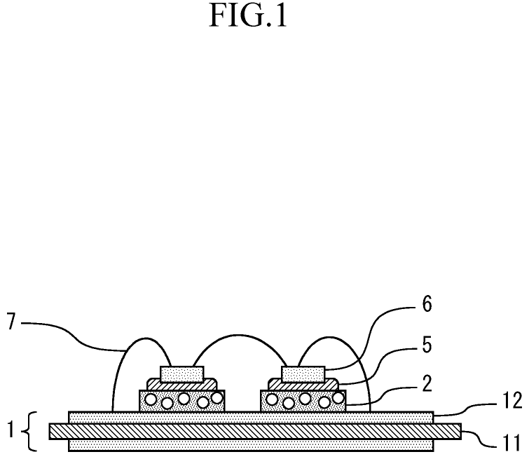

FIG. 1 is a cross-sectional view according to a first embodiment of the present invention. A bonding structure in the first embodiment includes an insulating substrate 1. The insulating substrate 1 includes circuit patterns 12, respectively, on an upper surface and a lower surface of a ceramic substrate 11. The ceramic substrate 11 is composed of an inorganic ceramic material such as alumina (Al2O3), aluminum nitride (AlN), or silicon nitride (Si3N4), and the circuit pattern 12 is composed of aluminum (Al), copper (Cu), or their alloy.

A porous material 2 is bonded to an upper surface of the insulating substrate 1. The porous material 2 is formed such that its holes each have a pore size not more than the particle size of a metal component contained in a bonding material 5, described below. The porous material 2 has desirably a porosity not more than 80%, and can be composed of Cu or silver (Ag), for example. The holes of the porous material 2 function as a path from which an organic component contained in the bonding material 5 is volatilized. Accordingly, the holes of the porous material 2 are desirably connected to the outer periphery of the porous material 2. An example of the porous material 2 technically established is a lotus metal as a porous metal having a large number of elongated pores arranged therein in the same direction. Further, the thermal conductivity of the porous material 2 is desirably 40 W/m□K or more. It has been reported that the higher the porosity is, the lower the thermal conductivity becomes. Accordingly, the porosity is desirably low even in that sense.

A method for bonding the circuit pattern 12 included in the insulating substrate 1 and the porous material 2 is direct bonding, and particularly is preferably pressure bonding. In pressure bonding, materials are made to adhere to each other, and are heated and pressurized, to advance solid phase diffusion bonding. As a result, a clearance between the materials can be reduced to integrate bonding interfaces. Examples of a condition of two materials that can be pressure-bonded to each other include a condition that the respective surface roughnesses of the materials are less than 100 nm and a condition that a substance that inhibits bonding, such as foreign matter, dirt, and an oxide film, does not exist on a bonding surface. Examples of direct bonding other than pressure bonding include welding and ultrasound bonding.

A semiconductor device 6 is bonded to an upper surface of the porous material 2 using the bonding material 5. The bonding material 5 is a paste-like bonding material in which metal nanoparticles of Ag, Cu, or the like are dispersed in an organic solvent with the metal nanoparticles protected by an organic film. When the paste-like bonding material 5 is heated, the organic film is volatilized so that the metal nanoparticles are exposed to a surface of the bonding material 5, and thus is sintered to function as a bonding material. That is, when the bonding material 5 is used, bonding can be performed without pressurization. Accordingly, a damage to the semiconductor device at the time of bonding can be minimized.

An example of the semiconductor device 6 is an IGBT (insulated gate bipolar transistor), a MOSFET (metal oxide semiconductor field effect transistor), or an SBD (Schottky barrier diode) composed of silicon (Si) or the like.

A method for bonding the porous material 2 and the semiconductor device 6 to each other will be described. First, the bonding material 5 is applied on the porous material 2. In this case, screen printing is used so that the thickness of the bonding material 5 is constant. When the semiconductor device 6 is then mounted on the bonding material 5, followed by heating, an organic solvent and an organic protective film contained in the bonding material 5 are decomposed and volatilized so that the metal nanoparticles are exposed to the surface of the bonding material 5. When the exposed metal nanoparticles are bonded to one another or the metal nanoparticles are bonded to the porous material 2 and the semiconductor device 6, sintering progresses.

When bonding is performed using the bonding material 5, an organic component such as the organic solvent and the organic protective film needs to be volatilized in a sintering process, as described above. However, when the semiconductor device 6 and the circuit pattern 12 are bonded to each other using the bonding material 5, a volatilization path of the organic component is only a side surface of a bonding portion. Therefore, particularly if the bonding portion is wide, i.e., if the area of the semiconductor device 6 is large, the organic component easily remains in the vicinity of the center of the semiconductor device 6. Accordingly, there occurs a problem that a bonding strength decreases, for example. The semiconductor device 6 and the circuit pattern 12 can be satisfactorily bonded to each other even if the area of the semiconductor device 6 is large by installing the porous material 2 therebetween to set the pores of the porous material 2 as the volatilization path of the organic component.

In a conventional example, bonding using a bonding material has been performed two times on an upper surface and a lower surface of a porous material. However, when printing and sintering are collectively performed, the bonding material printed the first time is crushed from above when printed the second time. Accordingly, a force is non-uniformly applied to an entire bonding surface. A force to be applied to the bonding material affects the pressure and the speed of screen printing and the viscosity of the bonding material. Accordingly, the thickness of the bonding material becomes non-uniform, thereby raising concerns of a deterioration in product reliability. When printing and sintering are performed for each bonding surface, a printing and sintering process is performed two times. Accordingly, a large number of man-hours are required.

In the present disclosure, a lower surface of the porous material 2 is directly bonded using pressure bonding. And an upper surface of the porous material 2 is bonded using the bonding material 5. That is, bonding using the bonding material 5 is performed only once. Accordingly, a semiconductor apparatus in which the thickness of a bonding material 5 is not non-uniform and a required number of man-hours is small can be manufactured. Further, the thickness of the bonding material 5 is uniform so that a bonding strength is improved. Accordingly, the product life of the semiconductor apparatus can also be improved.

When the upper surface of the porous material 2 is bonded using pressure bonding, the semiconductor device 6 needs to be heated and pressurized, thereby raising concerns that damages such as a flaw and a crack occur in the semiconductor device 6. However, when the upper surface of the porous material 2 is bonded using the bonding material 5, bonding can be performed without pressurization, as described above. Accordingly, the damages to the semiconductor device 6 can be minimized.

When pressure bonding is performed, interfaces are integrated by the progress of diffusion bonding, and are bonded to each other to such a degree as not to be discriminable in cross section. Accordingly, heat resistance increases to a melting point of a metal. For bonding using the bonding material 5, heat resistance also increases to a melting point of a metal due to the above-described principle. That is, even if the lower surface of the porous material 2 is bonded by pressure bonding, there is no problem with heat resistance.

The semiconductor device 6 is connected to the circuit pattern 12 by a wire wiring 7. The wire wiring 7 is a metal wiring composed of Al, Cu, or their alloy, for example.

### Second Embodiment

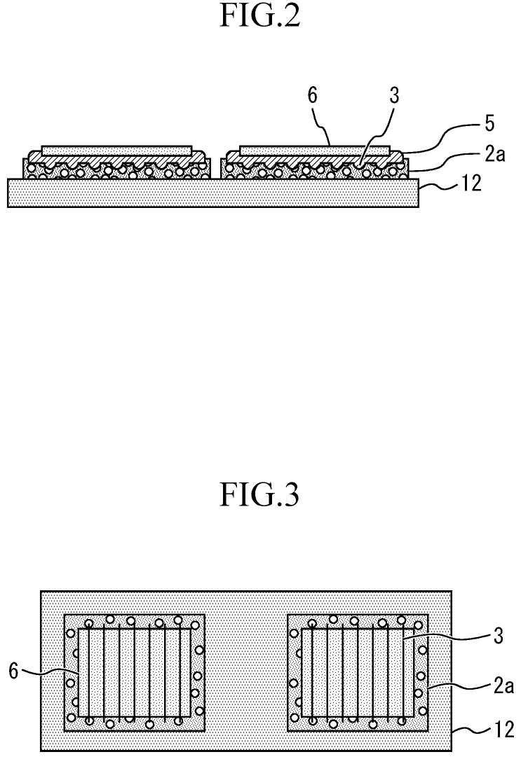

FIG. 2 is a cross-sectional view of a bonding structure according to a second embodiment of the present disclosure. The bonding structure according to the second embodiment includes a porous material 2a instead of the porous material 2. A porous material 2a includes recesses 3 formed by machining processing or the like. When the bonding structure includes the porous material 2a, an organic component in the vicinity of the center of the semiconductor device 6 can be efficiently volatilized, like in the first embodiment. Further, the porous material 2a has the recesses 3, whereby a contact area of the porous material 2a with the bonding material 5 increases. Accordingly, the organic component can be more efficiently volatilized. Therefore, the semiconductor device 6 can be satisfactorily bonded.

FIG. 3 is a plan view of the bonding structure according to the second embodiment of the present disclosure. Although the recesses 3 are positioned in a region on which the semiconductor device 6 is placed, as respectively indicated by straight lines in FIG. 3, the length of each of the recesses 3 may be long beyond the region. The width of the recess 3 is larger than the particle size of metal nanoparticles contained in the bonding material 5, and is smaller than the width of the semiconductor device 6.

### Third Embodiment

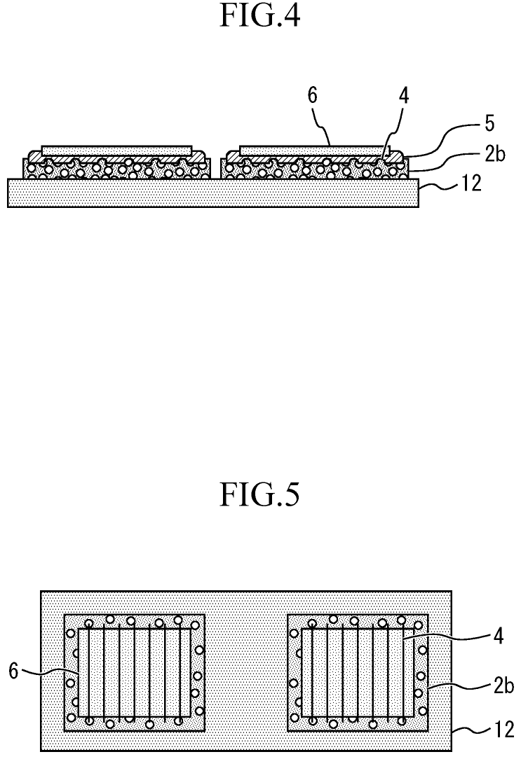

FIG. 4 is a cross-sectional view of a bonding structure according to a third embodiment of the present disclosure. The bonding structure according to the third embodiment includes a porous material 2b instead of the porous material 2. A porous material 2b includes projections 4 formed by machining processing or the like. When the bonding structure includes the porous material 2b, an organic component in the vicinity of the center of a semiconductor device 6 can be efficiently volatilized, like in the first embodiment. Further, the porous material 2b has the projections 4, whereby a contact area of the porous material 2b with the bonding material 5 increases. Accordingly, the organic component can be more efficiently volatilized. Therefore, the semiconductor device 6 can be satisfactorily bonded.

The porous material 2b has the projections 4, whereby the bonding material 5 is thicker than the height of the projections 4. As a result, resistance to a shear stress by extension and contraction at the time of heating and cooling increases, and a crack or the like does not easily occur in a bonding layer. Accordingly, an improvement in product reliability can be expected.

FIG. 5 is a plan view of the bonding structure according to the third embodiment of the present disclosure. Although the projections 4 are positioned in a region on which the semiconductor device 6 is placed, respectively as indicated by straight lines in FIG. 5, the length of each of the projections 4 may be long beyond the region. The width of the projection 4 is larger than the particle size of metal nanoparticles contained in the bonding material 5, and is smaller than the width of the semiconductor device 6. The height of the projection 4 is smaller than the thickness of the bonding material 5.

### Fourth Embodiment

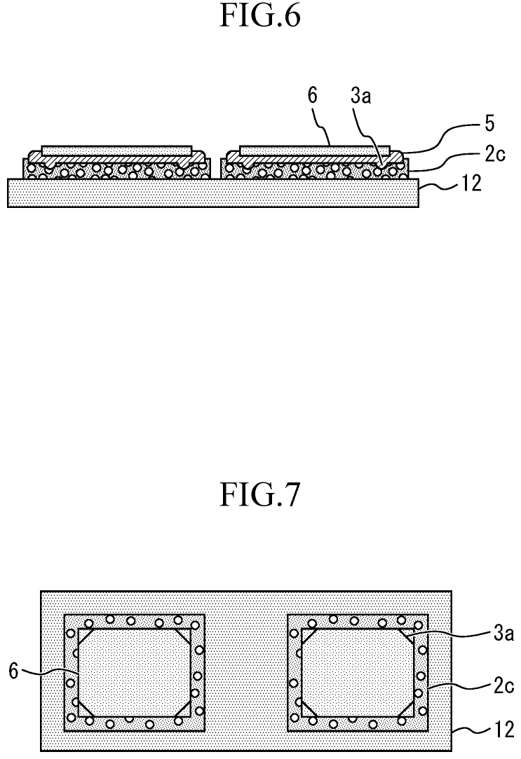

FIG. 6 is a cross-sectional view of a bonding structure according to a fourth embodiment of the present disclosure. The bonding structure according to the fourth embodiment includes a porous material 2c instead of the porous material 2. A porous material 2c includes recesses 3a formed by machining processing or the like. Although a mode in which recesses are formed is illustrated in the fourth embodiment, a mode in which projections are respectively formed at the same positions may be used.

FIG. 7 is a plan view of the bonding structure according to the fourth embodiment of the present disclosure. Each of the recesses 3a is positioned in a square-shaped region on which a semiconductor device 6 is placed, and is formed to have an intersection with two sides constituting each of internal angles, as indicated by a straight line in FIG. 7. The bonding structure includes the porous material 2c, whereby an organic component in the vicinity of the center of the semiconductor device 6 can be efficiently volatilized, like in the first embodiment. Further, the porous material 2c has the recess 3a so that an anchor effect is produced. Accordingly, a bonding strength at four corners from which the semiconductor device 6 is easily peeled off can be increased. As a result, the semiconductor device 6 can be satisfactorily bonded.

Although the semiconductor device 6 is formed of Si in the present disclosure, the semiconductor device 6 may be formed of a wide bandgap semiconductor having a larger band gap than that of Si. An example of the wide bandgap semiconductor is silicon carbide (SiC), gallium nitride (GaN)-based material, or diamond.

Obviously many modifications and variations of the present disclosure are possible in the light of the above teachings. It is therefore to be understood that within the scope of the appended claims the invention may be practiced otherwise than as specifically described.

The entire disclosure of a Japanese Patent Application No. 2022-012940, filed on Jan. 31, 2022 including specification, claims, drawings and summary, on which the Convention priority of the present application is based, are incorporated herein by reference in its entirety.

1. A semiconductor apparatus comprising:
an insulating substrate;
a porous material directly bonded to the insulating substrate; and
a semiconductor device bonded to the porous material via a bonding material containing metal nanoparticles.

2. The semiconductor apparatus according to claim 1, wherein the porous material has at least one recess on its bonding surface to the bonding material.

3. The semiconductor apparatus according to claim 1, wherein the porous material has at least one projection on its bonding surface to the bonding material.

4. The semiconductor apparatus according to claim 2, wherein the at least one recess comprises recesses respectively positioned just below four corners of the semiconductor device.

5. The semiconductor apparatus according to claim 3, wherein the at least one projection comprises projections respectively positioned just below four corners of the semiconductor device.

6. The semiconductor apparatus according to claim 1, wherein the semiconductor device is formed of a wide bandgap semiconductor.

7. The semiconductor apparatus according to claim 6, wherein the wide bandgap semiconductor is silicon carbide, a gallium nitride-based material, or diamond.
